(19) United States
(12) Patent Application Publication
(10) Pub. No.: US 2006/0094146 A1
(43) Pub. Date: May 4, 2006

(54) Emissive plastic optical fiber using phase separation and backlight unit for liquid crystal display using the same

(76) Inventors: Han Sol Cho, Daejeon-Si (KR); Jin Sung Choi, Daejeon-Si (KR); Jin Taek Hwang, Daejeon-Si (KR); Mu Gyeom Kim, Suwon-Si (KR); Byoung Joo Ra, Yongin-Si (KR)

Correspondence Address: HARNESS, DICKEY & PIERCE, P.L.C., P.O. BOX 8910, RESTON, VA, 20195, US

(21) Appl. No.: 11/296,475

(22) Filed: Dec. 8, 2005

Related U.S. Application Data
(62) Division of application No. 10/756,548, filed on Jan. 14, 2004.

(30) Foreign Application Priority Data
Jan. 14, 2003 (KR) 2003-2490

(51) Int. Cl. H01L 21/00; G02B 6/02

(52) U.S. Cl. 438/31; 385/123

(57) ABSTRACT

An emissive plastic optical fiber using phase separation and a backlight unit for a liquid crystal display using the emissive plastic optical fiber. The emissive plastic optical fiber is fabricated by inducing phase separation in a polymer which forms a core and/or a clad, which can be applied to the backlight unit for a liquid crystal display.

This non-provisional application claims priority under 35 U.S.C. § 119(a) on Korean Patent Application No. 2003-2490 filed on Jan. 14, 2003, which is herein incorporated by reference.

### BACKGROUND OF THE INVENTION

1. Field of the Invention

The present invention relates to an emissive plastic optical fiber using phase separation and a backlight unit for a liquid crystal display using the emissive plastic optical fiber. More particularly, the present invention relates to an emissive plastic optical fiber fabricated by inducing phase separation in a polymer which forms a core and/or a clad, and a backlight unit for a liquid crystal display using the emissive plastic optical fiber.

2. Description of the Related Art

Generally, a side-light type system and a multi-lamp type system are employed in currently used backlight units for liquid crystal displays. In the side-light type system, a cold cathode fluorescent tube is disposed outside the periphery of the light guide plate. In the multi-lamp type system, two or four lamps are disposed outside the periphery of a light guide plate to increase luminance of a backlight unit. Conventional light guide plates used in liquid crystal displays are elements constituting the side-light type backlight unit. A side-light type illuminator is disclosed in Japanese Patent Laid-open No. 57-128383. This illuminator includes a cold cathode gas discharge tube, a hot cathode gas discharge tube, a bulb or an LED light source positioned at one side of a luminescent surface. The shape of the illuminator may vary depending on the intended application, for example, it can have an ‘L’, ‘U’ and ‘W’ configuration. In the illuminator, a light emitted from a light source enters a light guide plate through a side surface and is scattered at a variety of angles by a light scattering unit installed on a light reflective-surface. Then, the light is emitted from a diffusing plate toward a viewer's side through a polarizing plate.

Since the side-light type backlight unit includes a light source disposed at a side surface of the light guide plate, it can contribute to a reduction in the thickness and weight of liquid crystal displays. Accordingly, the side-light type backlight unit is employed as an illuminator of liquid crystal displays for laptop, notebook computers or personal computers (PCs). Since portable devices such as notebook computers are driven by embedded batteries, low power consumption is required for side-light type illuminators. The backlight unit used in portable devices, e.g., notebook computers, is responsible for 60% of the power consumption. For improved light transmission efficiency and reduced power consumption, elements such as a light guide plate, a diffusing plate and a polarizing plate must have high transparency and uniform luminance. In addition, the light guide plate of the backlight unit bears the largest portion (60%) in the thickness of the liquid crystal display monitors of portable devices. Accordingly, a lightweight and thin light guide plate is required for the manufacture of lightweight portable devices.

FIG. 1 shows the structure of an embodiment of the above-mentioned side-light type illuminator. A liquid crystal panel 8 performs the function of creating character or image information by controlling light transmittance at a desired position on a screen. The liquid crystal panel 8 itself does not emit light, and a light from an illuminating part. A cold cathode fluorescent tube is typically used as a light source 1, which is provided with a lamp cover 2.

In FIG. 1, a light guide plate 5 has an inclined back surface opposite to a light-emitting surface, which is wedge-shaped. But the back surface may have other shapes, such as a flat or specially an irregular shape. In addition to the light guide plate 5, the side-light type illuminator includes a plurality of auxiliary sheets such as a reflecting plate 3, a diffusing plate 6 and a polarizing plate 7 which are sequentially disposed on the light guide plate.

As shown in FIG. 1, light-scattering patterns 4 are formed on the back surface of the light guide plate 5 opposite to the light-emitting surface by dot-printing using white ink, so that light-emission efficiency is improved. However, the formation of the light scattering patterns by white ink printing has the following problems.

As the patterns become fine, printability of white ink is poor and uniform light reflectability cannot be attained. In addition, since discoloration of the patterns is likely to occur with the passage of time, the luminance deteriorates and thus the life of the illuminator is shortened.

In an effort to overcome the above problems, non-print light guide plates were developed without involving any printing process. U.S. Pat. No. 6,123,431 discloses a non-print light guide plate on which grooves are formed as light-scattering patterns. In addition, U.S. Pat. No. 5,881,201 discloses a non-print light guide plate in which inorganic or organic particles having different refractive indices are dispersed, thereby exhibiting a scattering function due to the refractive index difference, and further acting as a diffusing plate.

On the other hand, the present inventor has found that an emissive plastic optical fiber fabricated by adding a scattering agent to the plastic optical fiber exhibits an improved scattering function sufficient to replace conventional light guide plates for illuminating liquid crystal displays, thus defining a new conceptual illuminator (see, Korean Patent Appln. No. 2002-77401).

Typical plastic optical fibers consist of a core and a clad and the refractive index of the core is higher than that of the clad. When light is irradiated to the core, the light is totally reflected by the refractive index difference at the interface between the core and the clad, and propagates in a straight patch. The plastic optical fibers are classified into those for illumination and communication according to how far the incident light propagates, or whether the refractive index variation from core to clad increases in a step or graded manner in a radial direction.

Also, some emissive plastic optical fibers have been reported. For example, Bastiaansen et al. from Eindhoven Univ. proposed an emissive plastic optical fiber in which the reflective index of the core is lower than that of the clad and bead-shaped copolymer particles are distributed on the surface of the fiber. (POF world 2000, Bastiaansen et al., Eindhoven Univ.) Such an emissive plastic optical fiber is utilized in signboards in U.S. Pat. No. 3,718,814.

Furthermore, the present inventor has suggested a new concept of an illuminator manufactured by applying the emissive plastic optical fiber to a backlight unit for a liquid crystal display (Korean Patent Appln. No. 2002-77401)

### SUMMARY OF THE INVENTION

The present invention provides a new conceptual emissive plastic optical fiber using phase separation.

Another feature of the present invention is to provide a backlight unit for a liquid crystal display using the emissive plastic optical fiber.

In accordance with the present invention, there is provided an emissive plastic optical fiber comprising a core and a clad, the core and/or the clad being formed in an opaque phase by polymer phase separation.

In accordance with the present invention, there is further provided a method for fabricating an emissive plastic optical fiber, comprising the steps of: adding a clad reactant including at least one monomer or a prepolymer to a reactor, and polymerizing the clad reactant with the rotation of the reactor to form a clad; adding a core reactant including at least one monomer or a prepolymer to the reactor, and polymerizing the core reactant with the rotation of the reactor to form a core and to complete the fabrication of a preform for the plastic optical fiber, the core reactant having a refractive index identical to or lower than that of the clad reactant; and thermally drawing the preform, wherein at least one of the clad reactant and the core reactant is mixed with a monomer for phase separation

In accordance with the present invention, there is further provided a backlight unit for a liquid crystal display, comprising: a plurality of emissive plastic optical fibers having a constant length and arranged in intimate contact with each other in a line; and at least one light source disposed at one or both ends of the plastic optical fibers wherein each emissive plastic optical fiber comprises a core and a clad, the core and/or the clad being formed in an opaque phase by polymer phase separation.

In accordance with the present invention, there is further provided a liquid crystal display comprising the above backlight unit.

### BRIEF DESCRIPTION OF THE DRAWINGS

The present invention will become more fully understood from the detailed description given hereinbelow and the accompanying drawings, which are given by way of illustration only, and thus are not limitative of the present invention, and wherein:

FIG. 1 is a view schematically showing the structure of a conventional side-light type liquid crystal display;

FIGS. 2a and 2b are cross-sectional views showing structures of an emissive plastic optical fiber according to the present invention;

FIGS. 3a and 3b are graphs showing refractive index distributions of an emissive plastic optical fiber according to the present invention;

FIG. 4 is a perspective view showing the structure of a cavity-preventing type reactor, which is used for fabricating an optical fiber of the present invention; and

FIG. 5 is a view schematically showing the operational principle of a backlight unit for a liquid crystal display using the emissive plastic optical fiber of the present invention.

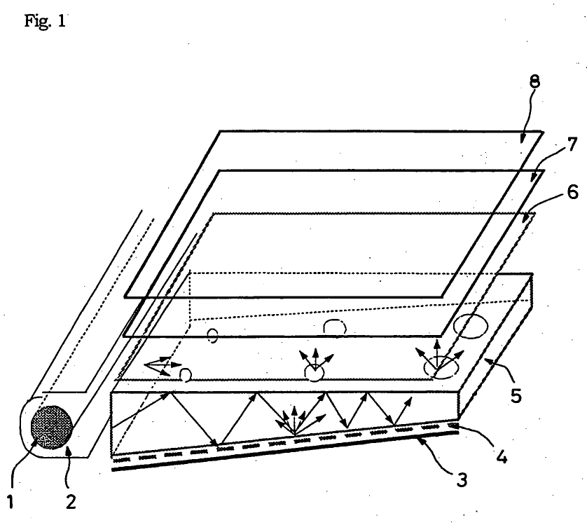

### DESCRIPTION OF THE PREFERRED EMBODIMENTS

Hereinafter, the present invention will be explained in more detail with reference to the accompanying drawings.

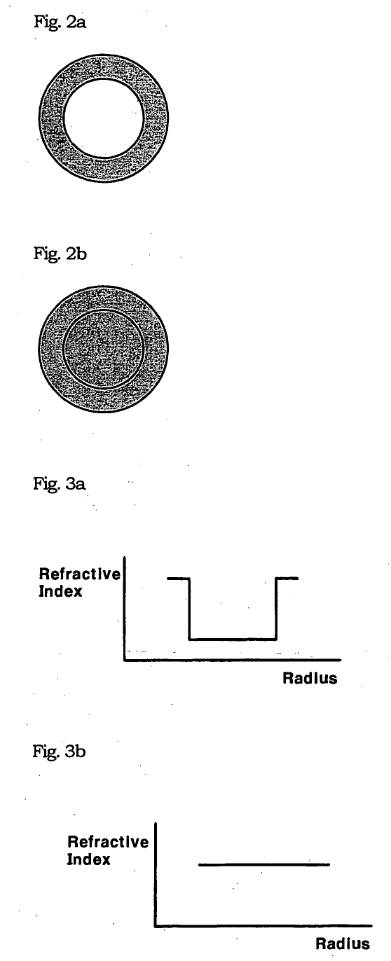

As shown in FIGS. 2a and 2b, since at least one of a core and a clad constituting an emissive plastic optical fiber according to the present invention is formed in an opaque phase by polymer phase separation, the emissive plastic optical fiber allows incident light to be dispersed and emitted.

FIGS. 3a and 3b shows refractive index distributions of the emissive plastic optical fiber according to the present invention. As shown in FIGS. 3a and 3b, the refractive index of the core may be lower than (step index type) or identical to (plat type) that of the clad.

The plastic optical fiber of the present invention is fabricated by a method comprising the steps of: adding a clad reactant to a reactor, and polymerizing the clad reactant with the rotation of the reactor to form a clad; adding a core reactant to the reactor, and polymerizing the core reactant with the rotation of the reactor to form a core and to complete fabrication of a preform for a plastic optical fiber, the core reactant having a refractive index identical to or less than that of the clad reactant; and thermally drawing the preform into a desired diameter. In this method, first at least one of either the clad reactant and the core reactant is compounded in such a way that phase separation takes place, followed by polymerization into an opaque copolymer by phase separation to provide an emissive plastic optical fiber. For example, when MMA (methyl methacrylate) is used as an optical monomer, a material such as 3FM (trifluoroethylmethacrylate), PVDF (polyvinylidenefluoride), Sty (styrene), etc. can be mixed to induce polymer phase separation. For example, in the case of the reaction of MMA and styrene, although the reaction rates of MMA and styrene are similar, MMA reacts first in the reaction mixture of MMA and styrene, particularly where the content of styrene is, for example, 20% by weight or more. Since MMA reacts first before styrene reacts, the MMA homopolymer is formed first and there occurs phase separation at the surface of the homopolymer resulting in an opaque phase. This phenomenon particularly occurs when the content of styrene is high.

In the present invention, an emissive plastic optical fiber comprising a transparent core and an opaque clad as shown in FIG. 2a, is more preferred because its emission intensity is increased.

The preform for an optical fiber can be produced by a method using a cylindrical reactor in a centrifugal field, or a method using a cavity-preventing type reactor. These methods are described in U.S. Pat. No. 6,429,263 and US Patent Publication No. 2003-30159, respectively, all of which were invented by the present inventor. In addition to the above methods, other known methods may be used, as long as they do not detract from the object of the present invention. A cavity-preventing type reactor disclosed in US Patent Publication No. 2003-30159 is more preferred because it can prevent the formation of a cavity in the production of the preform for an optical fiber, and the step for feeding a monomer into the cavity can be eliminated.

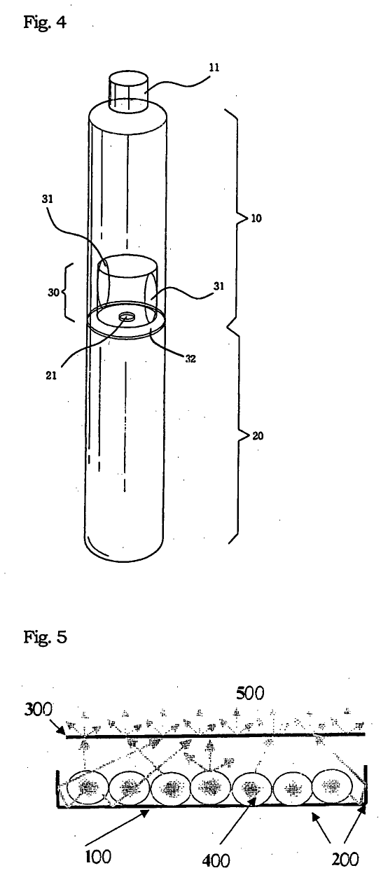

FIG. 4 shows a representative example of the cavity-preventing type reactor. Referring to FIG. 4, the reactor includes (a) an introduction part 10 equipped with a reactant inlet port 11 through which a reactant is introduced into the reactor; (b) a reaction part 20 having a flow passage 21, whereby the introduction part 10 is connected to the reaction part 20, the flow passage 21 being formed at the center of a blocking wall 32 provided between the introduction part 10 and the blocking wall 32; and (c) one or more cavity-preventing structures 30 equipped with one or more flow passages 31 through which the reactant flows from the introduction part 10 to the reaction part 20 to prevent a cavity from being formed at the reactant inlet port 11 of the introduction part 10 from extending to the reaction part 20 during rotation of the reactor.

The reactant used for the fabrication of the preform for a plastic optical fiber includes at least one monomer, a polymerization initiator and a chain transfer agent. As the polymerization initiator, a photopolymerization initiator and a thermal polymerization initiator can be used alone or in combination. A combination of the photopolymerization initiator and the thermal polymerization initiator can be used to simultaneously perform photopolymerization and thermal polymerization processes.

Examples of the optical monomer used in the present invention include, but are not limited to, methylmethacrylate, benzylmethacrylate, phenylmethacrylate, 1-methylcyclohexylmethacrylate, cyclohexylmethacrylate, chlorobenzylmethacrylate, 1-phenylethylmethacrylate, 1,2-diphenylethylmethacrylate, diphenylmethylmethacrylate, furfuryl methacrylate, 1-phenylcyclohexylmethacrylate, pentachlorophenylmethacrylate, pentabromophenylmethacrylate, styrene, TFEMA (2,2,2-trifluoroethylmethacrylate) TFPMA (2,2,3,3-tetrafluoropropylmethacrylate), PFPMA (2,2,3,3,3-pentafluoropropylmethacrylate), HFIPMA (1,1,1,3,3,3-hexafluoroisopropylmethacrylate), HFBM (2,2,3,4,4,4-hexafluorobutylmethacrylate), HFBMA (2,2,3,3,4,4,4-heptafluorobutylmethacrylate) and PFOM (1H,1H-perfluoro-n-octylmethacrylate).

The kind of the monomer capable of causing phase separation after polymerization may vary depending on the kind of the optical monomer. For example, when the optical monomer is an acrylate monomer such as MMA (methyl methacrylate) or BMA (benzyl methacrylate), 3FM (trifluoroethylmethacrylate), VDF (vinylidenefluoride), styrene, etc. can be used as the monomer capable of causing phase separation after polymerization.

Examples of the thermal polymerization initiator used in the present invention include, but are not limited to, 2,2′-azobis(isobutyronitrile), 1,1′-azobis(cyclohexanecarbonitrile), 2,2′-azobis(2,4-dimethylvaleronitrile), 2,2′-azobis(methylbutyronitrile), di-tert-butyl peroxide, lauroyl peroxide, benzoyl peroxide, tert-butyl peroxide, azo-tert-butane, azo-bis-isopropyl, azo-normal-butane, di-tert-butyl peroxide, etc.

The thermal polymerization initiator is preferably added in an amount of not more than 5% by weight, and more preferably 0.5% by weight in terms of low optical loss of the optical fiber to be fabricated.

Examples of the photopolymerization initiator used in the present invention include, but are not limited to, 4-(para-tolylthio)benzophenone, 4,4′-bis(dimethylamino)benzophenone, 2-methyl-4′-(methylthio)-2-morpholino-propiophenone, 1-hydroxy-cyclohexyl-phenyl-ketone, 2-hydroxy-2-methyl-1-phenyl-propan-1-one, benzophenone, 1-[4-(2-hydroxyethoxy)-phenyl]-2-hydroxy-2-methyl-1-propan-1-one, 2-benzyl-2-methylamino-1-(4-morpholinophenyl)-butanone-1,2,2-dimethoxy-1,2-diphenylmethan-1-one, bis(2,4,6-trimethylbenzoyl)-phenylphosphinoxide, 2-methyl-1[4-(methylthio)phenyl]-2-morpholinopropan-1-one, bis(.etha.-5-2,4-cyclopentadien-1-yl)-bis(2,6-difluoro-3-(1H-pyrro-1-yl)-phenyl)titanium, etc.

The initiating rate and polymerization rate depending on the kind of the initiators are determined by the following factors: amount of the initiator added, intensity of a UV light source, distance from the light source, thickness of a the glass reactor wall, diameter of the reactor, reaction temperature and the like. The photopolymerization initiator is preferably added in an amount of not more than about 5% by weight, and more preferably 0.5% by weight in terms of low optical loss of the optical fiber to be fabricated.

Examples of the chain transfer agent used in the present invention include, but are not limited to, normal-butyl-mercaptan, lauryl mercaptan, octyl mercaptan, dodecyl mercaptan, 1-butanethiol, etc.

In order to allow smooth heat transfer for the polymerization process in the production of the preform for the emissive plastic optical fiber in accordance with the present invention, the preform preferably has a radius of 1˜10 cm. In addition, the length of the preform is preferably set at about 100 cm or less so as to be suitable for a common thermal drawing.

The emissive plastic optical fiber fabricated in accordance with the method of the present invention can replace conventional light guide plates to provide a backlight unit for a liquid crystal display. The backlight unit is manufactured by arranging a plurality of the emissive plastic optical fibers of the present invention, and disposing at least one light source at one or both ends of the emissive plastic optical fibers. FIG. 5 is a conceptual diagram showing the operational principle of the backlight unit according to the present invention, wherein element 100 is a backlight unit, element 200 is a reflective plate, element 300 is a light guiding plate, element 400 is an emissive plastic optical fiber and element 500 is a light.

The replacement of conventional light guide plates with the emissive plastic optical fibers of present invention has the advantage that the emissive plastic optical fiber provides excellent luminance uniformity without reducing the luminance, compared to conventional light guide plates. Above all, the thickness of the fiber can be controllably minimized, compared to conventional light guide plates.

At this time, the diameter of the emissive plastic optical fiber is in the range of 0.001 μm˜10 cm, and preferably 0.01 μm˜5 cm.

A white LED or cold cathode fluorescent tube is preferably used as the light source.

Hereinafter, the present invention will be described in more detail with reference to the following examples. However, these Examples are given for the purpose of illustration and thus should not be construed as limiting the scope of the present invention.

In these Examples, a cavity-preventing type reactor shown in FIG. 4 is used. The cavity-preventing type reactor has a 50 mm wide and 400 mm high main reaction part, and a 50 mm wide and 200 mm high introduction part.

A jacket reactor equipped with a circulator is used to prepare a prepolymer using a thermal polymerization initiator, while a transparent reactor equipped with a UV lamp is used to prepare a prepolymer using a photopolymerization initiator. In the case where the photopolymerization and thermal polymerization are simultaneously carried out, a reactor equipped with a circulator and an UV lamp are used to prepare the prepolymer.

2,2′-azobis isobutyronitrile (hereinafter referred to as ‘AIBN’) is used as the thermal polymerization initiator. 2-hydroxy-2-methyl-1-phenyl-propan-1-one (hereinafter referred to as ‘HMPP’) is used as a photopolymerization initiator. As a chain transfer agent, 1-butanethiol (hereinafter referred to as ‘1-BuSH’) is used.

### PREPARATIVE EXAMPLE 1

400 g of styrene is added to 510 g of MMA (methyl methacrylate), and AIBN and 1-BuSH are added thereto so that the concentration of AIBN and 1-BuSH is 0.066% and 0.2% by weight, respectively, to prepare a first monomer solution. The monomer mixture is polymerized at 75° C. for 1 hour with vigorous stirring. The polymer thus prepared is charged into a main reaction part of a cavity-preventing type reactor, and heated at a rotational speed of 3,000 rpm and a temperature of 75° C. for 24 hours to form a transparent clad. Separately, AIBN, HMPP and 1-BuSH are added to 338 g of MMA so that the concentration of AIBN, HMPP and 1-BuSH is 0.066%, 0.022% and 0.3% by weight in MMA, respectively, to prepare a second monomer solution. The second monomer solution thus prepared is charged into a jacket reactor, and heated to 75° C. for 40 minutes to prepare a prepolymer. The prepolymer is introduced into the cavity-preventing type reactor in which the clad was previously formed. The cavity-preventing type reactor is mounted on a reaction apparatus capable of simultaneously carrying out heating and UV irradiation, after which the prepolymer is polymerized at 3,000 rpm and 75° C. for 12 hours under UV irradiation to produce a preform for an erissive plastic optical fiber in a yield of 93%. A 0.55 mm thick optical fiber was drawn from the preform.

### PREPARATIVE EXAMPLE 2

500 g of VDF (vinylidenefluoride) is added to 510 g of MMA (methyl methacrylate), and AIBN and 1-BuSH are added thereto so that the concentration of AIBN and 1-BuSH is 0.066% and 0.2% by weight, respectively, to prepare a first monomer solution. The monomer mixture is polymerized at 75° C. for 1 hour with vigorous stirring. The polymer thus prepared was charged into a main reaction part of a cavity-preventing type reactor, and heated at a rotational speed of 3,000 rpm and a temperature of 75° C. for 24 hours to form a transparent clad. Separately, AIBN, HMPP and 1-BuSH are added to 338 g of MMA so that the concentration of AIBN, HMPP and 1-BuSH is 0.066%, 0.022% and 0.3% by weight in MMA, respectively, to prepare a second monomer solution. The second monomer solution thus prepared is charged into a jacket reactor, and heated to 75° C. for 10 minutes to prepare a prepolymer. The prepolymer is introduced into the cavity-preventing type reactor in which the clad is previously formed. The cavity-preventing type reactor is mounted on a reaction apparatus capable of simultaneously carrying out heating and UV irradiation, after which the prepolymer is polymerized at 3,000 rpm and 75° C. for 12 hours under UV irradiation to produce a preform for an emissive plastic optical fiber in a yield of 91%. A 0.55 mm thick optical fiber is drawn from the preform.

### PREPARATIVE EXAMPLE 3

200 g of 3FM (trifluoroethylmethacrylate) is added to 510 g of MMA (methyl methacrylate), and AIBN and 1-BuSH are added thereto so that the concentration of AIBN and 1-BuSH is 0.066% and 0.2% by weight, respectively, to prepare a first monomer solution. The monomer mixture is polymerized at 75° C. for 1 hour with vigorous stirring. The polymer thus prepared is charged into a main reaction part of a cavity-preventing type reactor, and heated at a rotational speed of 3,000 rpm and a temperature of 75° C. for 24 hours to form a clad having an opaque interface. Separately, AIBN, HMPP and 1-BuSH are added to 400 g of MMA so that the concentration of AIBN, HMPP and 1-BuSH is 0.066%, 0.022% and 0.3% by weight in MMA, respectively, to prepare a second monomer solution. The second monomer solution thus prepared is charged into a jacket reactor, and heated to 75° C. for 10 minutes to prepare a prepolymer. The prepolymer is introduced into the cavity-preventing type reactor in which the clad is previously formed. The cavity-preventing type reactor is mounted on a reaction apparatus capable of simultaneously carrying out heating and UV irradiation, after which the prepolymer is polymerized at 3,000 rpm and 75° C. for 12 hours under UV irradiation to produce a preform for an emissive plastic optical fiber in a yield of 90%. A 0.55 mm thick optical fiber is drawn from the preform.

### PREPARATIVE EXAMPLE 4

100 g of 3FM (trifluoroethylmethacrylate) and 100 g of styrene are added to 510 g of MMA (methyl methacrylate), and AIBN and 1-BuSH are added thereto so that the concentration of AIBN and 1-BuSH is 0.066% and 0.2% by weight, respectively, relative to the total monomers, to prepare a first monomer solution. The monomer mixture is polymerized at 75° C. for 1 hour with vigorous stirring. The polymer thus prepared is charged into a main reaction part of a cavity-preventing type reactor, and heated at a rotational speed of 3,000 rpm and a temperature of 75° C. for 24 hours to form a clad having an opaque interface. Separately, AIBN, HMPP and 1-BuSH are added to 400 g of MMA so that the concentration of AIBN, HMPP and 1-BuSH was 0.066%, 0.022% and 0.3% by weight in MMA, respectively, to prepare a second monomer solution. The second monomer solution thus prepared is charged into a jacket reactor, and heated to 75° C. for 10 minutes to prepare a prepolymer. The prepolymer is introduced into the cavity-preventing type reactor in which the clad is previously formed. The cavity-preventing type reactor is mounted on a reaction apparatus capable of simultaneously carrying out heating and UV irradiation, after which the prepolymer is polymerized at 3,000 rpm and 75° C. for 12 hours under UV irradiation to produce a preform for an emissive plastic optical fiber in a yield of 91%. A 0.55 mm thick optical fiber is drawn from the preform.

### PREPARATIVE EXAMPLE 5

50 g of 3FM, 150 g of styrene and 100 g of VDF are added to 510 g of MMA (methyl methacrylate), and AIBN and 1-BuSH are added thereto so that the concentration of AIBN and 1-BuSH is 0.066% and 0.2% by weight, respectively, relative to the total monomers, to prepare a first monomer solution. The monomer mixture is polymerized at 75° C. for 1 hour with vigorous stirring. The polymer thus prepared is charged into a main reaction part of a cavity-preventing type reactor, and heated at a rotational speed of 3,000 rpm and a temperature of 75° C. for 24 hours to form a clad having an opaque interface. Separately, AIBN, HMPP and 1-BuSH are added to a mixture of 400 g of MMA, 50 g of 3FM and 10 g of styrene so that the concentration of AIBN, HMPP and 1-BuSH was 0.066%, 0.022% and 0.3% by weight in MMA, respectively, to prepare a second monomer solution. The second monomer solution thus prepared is charged into a jacket reactor, and heated to 75° C. for 10 minutes to prepare a prepolymer. The prepolymer is introduced into the cavity-preventing type reactor in which the clad is previously formed. The cavity-preventing type reactor is mounted on a reaction apparatus capable of simultaneously carrying out heating and UV irradiation, after which the prepolymer is polymerized at 3,000 rpm and 75° C. for 12 hours under UV irradiation to produce a preform for an emissive plastic optical fiber in a yield of 91%. A 0.55 mm thick optical fiber is drawn from the preform.

### EXAMPLES 1-3

The emissive plastic optical fibers fabricated in Preparative Examples 1 to 3 are constructed into flat bundles, respectively. A reflective tape (RF188, Sujimoto Electro Mechanical Corp.) is attached to side sections other than a light-emitting surface, a cold cathode lamp (tube diameter: 2.4 mm, Harrison Electro mechanical Corp.) is installed, and a reflector (GR38W, Gimoto Company) is attached around the lamp and an incident surface of a light guide plate. A light diffusing sheet (PCMSA, TM Gimoto Electro mechanical Corp.) is disposed on the light-emitting surface, and a reflecting sheet (RF188, TM Gimoto Electro mechanical Corp.) is disposed at a side opposite to the light-emitting surface of the light guide plate to manufacture flat light source units. Luminance and impact resistance of the light source units are evaluated. The results are shown in Table 1 below.

TABLE 1

| | Luminance | Shock Resistance |
|---|---|---|
| Example 1 | Δ | Δ |
| Example 2 | ◯ | ◯ |
| Example 3 | ⊚ | ⊚ |

Physical properties of the light source units were measured as follows.

After 3 points spaced at the same interval on the light guide plates of each emissive plastic optical fiber are selected, luminance at each point is measured using a luminance meter (BM-7, Tpcon Corp.). The luminance is evaluated by the following equation: Luminance (%)=(Minimum value/Maximum value)×100, and then judged based on the following criteria:
⊚: >88%
∘: ≧85%, <88%
Δ: ≧82%, <85%

(2) Mechanical strength of the light source units is evaluated by shock resistance measured based on a falling test. Missile-shaped weights (10 g) having a radius of ¾ inches are dropped from a height of 50 cm to the same position of 10 light guide plates. The occurrence of fissures or cracks on the light guide plates is observed. The mechanical strength of the light guide plates are judged based on the following criteria:
: No fissure or crack is observed in 10 light guide plates.
: Fissures or cracks are observed in 1-3 out of 10 light guide plates.
: Fissures or cracks are observed in 4-6 out of 10 light guide plates.

### EXAMPLES 4-5

The emissive plastic optical fibers fabricated in Preparative Examples 4 and 5 are constructed into flat bundles, respectively. A reflective tape (RF188, Sujimoto Electro Mechanical Corp.) is attached to side sections other than a light-emitting surface, a white LED lamp (tube diameter: ≦1 mm, Harrison Electro mechanical Corp.) is installed, and a reflector (GR38W, Gimoto Company) is attached around the lamp and an incident surface of a light guide plate. A light diffusing sheet (PCMSA, TM Gimoto Electro mechanical Corp.) was disposed on the light-emitting surface, and a reflecting sheet (RF188, TM Gimoto Electro mechanical Corp.) is disposed at a side opposite to the light-emitting surface of the light guide plate to manufacture flat light source units. Luminance and impact resistance of the light source units are evaluated. The results are shown in Table 2 below.

TABLE 2

| | Luminance | Shock Resistance |
|---|---|---|
| Example 4 | ◯ | ◯ |
| Example 5 | Δ | Δ |

As apparent from the above description, the present invention provides an emissive plastic optical fiber with a new structure which can be applied to a backlight unit for a liquid crystal display.

Although the preferred embodiments of the present invention have been disclosed for illustrative purposes, those skilled in the art will appreciate that various modifications, additions and substitutions are possible, without departing from the spirit and scope of the invention as defined by the accompanying claims.

1.-3. (canceled)

4. A method for fabricating an emissive plastic optical fiber, comprising the steps of:
adding a clad reactant including at least one monomer or a prepolymer to a reactor, and polymerizing the clad reactant with rotation of the reactor to form a clad;
adding a core reactant including at least one monomer or a prepolymer to the reactor, and polymerizing the core reactant with rotation of the reactor to form a core and to complete the fabrication of a preform for a plastic optical fiber, the core reactant having a refractive index substantially identical to or lower than that of the clad reactant; and
thermally drawing the preform,
wherein at least one of the clad reactant and the core reactant is mixed with a monomer for phase separation.

5. The method for fabricating an emissive plastic optical fiber according to claim 4, wherein the reactor is a cylindrical reactor or a cavity-preventing type reactor.

6. The method for fabricating an emissive plastic optical fiber according to claim 4, wherein the monomer is selected from the group consisting of methylmethacrylate, benzylmethacrylate, phenylmethacrylate, 1-methylcyclohexylmethacrylate, cyclohexylmethacrylate, chlorobenzyl-methacrylate, 1-phenyl-ethylmethacrylate, 1,2-diphenylethylmethacrylate, diphenylmethylmethacrylate, furfuryl methacrylate, 1-phenylcyclohexylmethacrylate, pentachlorophenyl-methacrylate, pentabromophenylmethacrylate, styrene, TFEMA (2,2,2-trifluoroethylmethacrylate), TFPMA (2,2,3,3-tetrafluoropropylmethacrylate), PFPMA (2,2,3,3,3-pentafluoropropylmethacrylate), HFIPMA (1,1,1,3,3,3-hexafluoroisopropylmethacrylate), HFBM (2,2,3,4,4,4-hexafluorobutyl-methacrylate), HFBMA (2,2,3,3,4,4,4-heptafluorobutylmethacrylate) and PFOM (1H,1H-perfluoro-n-octylmethacrylate).

7. The method for fabricating an emissive plastic optical fiber according to claim 4, wherein the monomer for phase separation is selected from the group consisting of trifluoroethylmethacrylate, vinylidenefluoride, styrene, and methyl methacrylate.

8. The method for fabricating an emissive plastic optical fiber according to claim 4, wherein the reactant further includes a thermal polymerization initiator and/or a photopolymerization initiator and a chain transfer agent.

9. The method for fabricating an emissive plastic optical fiber according to claim 8, wherein the thermal polymerization initiator is at least one compound selected from the group consisting of 2,2′-azobis(isobutyronitrile), 1,1′-azobis(cyclohexanecarbonitrile), 2,2′-azobis(2,4-dimethylvaleronitrile), 2,2′-azobis(methylbutyronitrile), di-tert-butyl peroxide, lauroyl peroxide, benzoyl peroxide, tert-butyl peroxide, azo-tert-butyl peroxide, lauroyl peroxide, benzoyl peroxide, tert-butyl peroxide, azo-tert-butane, azo-bis-isopropyl, azo-normal-butane and di-tert-butyl peroxide.

10. The method for fabricating an emissive plastic optical fiber according to claim 8, wherein the photopolymerization initiator is at least one compound selected from the group consisting of 4-(para-tolylthio)benzophenone, 4,4-bis(dimethylamino)benzophenone, 2-methyl-4′-(methylthio)-2-morpholinopropiophenone, 1-hydroxy-cyclohexyl-phenyl-ketone, 2-hydroxy-2-methyl-1-phenyl-propan-1-one, benzophenone, 1-[4-(2-hydroxyethoxyl)-phenylk]-2-hydroxy-2-methyl-1-1propan-1-one, 2-benzyl-2-methylamino-1-(4-morpholinophenyl)-butanone-1,2,2-dimethoxy-1,2-diphenylmethan-1-one, bis(2,4,6-trimethylbenzoyl)-phenylphosphinoxide, 2-methyl-1[4-(methylthio)phenyl]-2-morpholinopropan-1 one and bis(.etha.-5,2,4-cyclopentadien-1yl)-bis(2,6-difluoro-3-(1H-pyrro-1-yl)-phenyl)titanium.

11. The method for fabricating an emissive plastic optical fiber according to claim 8, wherein the chain transfer agent is at least one compound selected from the group consisting of normal-butyl-mercaptan, lauryl mercaptan, octyl mercaptan, dodecyl mercaptan and 1-butanethiol.

12.-16. (canceled)
